(19) United States
(12) Patent Application Publication
(10) Pub. No.: US 2008/0273719 A1
(43) Pub. Date: Nov. 6, 2008

(54) Method and apparatus for controlling audio volume when switching electronic product channels

(75) Inventor: Hou-Cheng Chen, Taipei Hsien (TW)

Correspondence Address: BRUCE H. TROXELL;SUITE 1404, 5205 LEESBURG PIKE, FALLS CHURCH, VA, 22041, US

(73) Assignee: WISTRON CORP.

(21) Appl. No.: 11/896,282

(22) Filed: Aug. 30, 2007

(30) Foreign Application Priority Data
May 1, 2007 (TW) 096115487

(51) Int. Cl. H03G 3/20

(52) U.S. Cl. 381/107

(57) ABSTRACT

Method and apparatus for controlling audio volume when switching electronic product channels is characterized by saving predetermined volume of each channel in a memory and outputting the responsive volume via a speaker, wherein the electronic product can output an audio volume in response to each channel as user preferable volume.

### BACKGROUND OF THE INVENTION

1. Field of the Invention

The present invention relates to a method and an apparatus for controlling audio volume of an electronic product and, more particularly to a method and an apparatus for controlling audio volume when switching an electronic product channels.

2. Description of Related Art

An electronic product, such as TV, radio, computer and so on, can respectively receive an audio signal transmitted from a variety of channels to output an audio volume responsive to the electronic product channels; and sequentially adjust the audio volume.

TW Patent No.I72854 discloses that a volume control device for using in a cable television set top converter or the like is calibrated for optimum television stereo channel separation. In brief, the TW Patent No.I72854 is related to disclose a volume control device for controlling an audio signal which has similar structure to FIG. 1 that controls a tuner 21 of an electronic product to output the audio signal through an antenna or a cable 10 as being for the optimum television stereo channel separation.

In addition, TW Patent Pub.No.200639679 discloses a system and method thereof for dynamically calibrating an audio volume of a system by the movement of a mouse roller, comprising: a pressing signal received unit for receiving a press control signal provided by when the mouse roller is pressed; a rolling signal received unit for receiving a rolling control signal provided by when the mouse roller is wheeling; a signal comparison analyzed unit for analyzing a pressing control signal and a rolling control signal, and sequentially providing a responsive volume command, and finally calibrating the outputted volume of operation system by an volume control unit in accordance with the volume command. In brief, the patent Pub.No.200639679 is related to disclose a system and a method for calibrating the volume of the system in accordance with the rolling control signal when mouse roller is wheeling.

Cable television system is capable of providing a variety of channels which enables user to navigate from one television program to another by a remote control as user desires.

As a user watches a television program, the audio volume responsive to the television program may be undesirable due to different audio signal output from cable television programs. At that time, the user needs to adjust this undesirable audio volume by a remote control. Furthermore, as the user navigates from the one television program to another, the audio volume level that is output by a television system may need to change again even though the volume settings remain unchanged. This non-requested change in volume level is undesirable. Under this circumstance, it can result in a user having to adjust the volume setting by a remote control in order to remain a desirable volume level.

However, the electronic product nowadays, such as TV, radio or computer and so on, could not enable user to set and save predetermined volume level responsive to each channel which are the drawbacks existing in the aforementioned prior arts. Thus, with the present invention relating to a method and an apparatus for audio volume control, it enables user to set and save the predetermined volume level so that the electronic product can automatically output user desirable volume when switching television programs.

### SUMMARY OF THE INVENTION

It is therefore a primary objective of the claimed invention to provide a method and an apparatus for controlling audio volume when switching channels of an electronic product which results in the electronic product can automatically output the audio volume responsive to each channel.

Another objective of the claimed invention is to provide a method and an apparatus for controlling audio volume, wherein the audio volume is predetermined by an electronic product in response to each channel when switching channels of an electronic product which results in the electronic product can automatically output the audio volume

The method for controlling audio volume in accordance with the present invention comprises the following steps:

When a microprocessor detects a channel signal value, the microprocessor automatically controls an audio processor to output an audio signal value that is responsive to the channel signal value and then output the responsive audio volume via a speaker. When a user switches channels of an electronic product from one channel to another, the audio volume responsive to each channel is predetermined by an electronic product and then is automatically output by the electronic product.

The apparatus for controlling audio volume in accordance with the present invention comprises a tuner, a microprocessor, a memory, a signal decoder and an audio processor. The tuner is capable of receiving a signal from an electronic product. The microprocessor is capable of detecting a channel signal value and an audio signal value, and further controlling the tuner to output an audio signal, which is responsive to the channel signal value, to the signal decoder. The signal decoder is capable of transmitting a decoded signal to the audio processor after the audio signal is decoded. With the adoption of the apparatus for controlling audio volume, the microprocessor directs the audio processor to transmit the audio signal value in response to the channel signal value which results in the responsive audio volume outputting via a speaker accordingly. Thus, when a user switches channels of an electronic, the electronic product can automatically output the predetermined volume level in response to each channel.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The features of the invention believed to be novel and the elements characteristic of the invention are set forth with particularity in the appended claims. The figures are for illustration purposes only and are not drawn to scale which follows taken in conjunction with the accompanying drawings in which:

FIG. 1 is a block diagram of an embodiment of an electronic product for implementing a method in accordance with the present invention;

FIG. 2 is a flowchart of 1^{st} embodiment for implementing a method in accordance with the present invention; and

FIG. 3 is a flowchart of 2nd embodiment for implementing a method in accordance with the present invention.

### DETAILED DESCRIPTION OF THE INVENTION

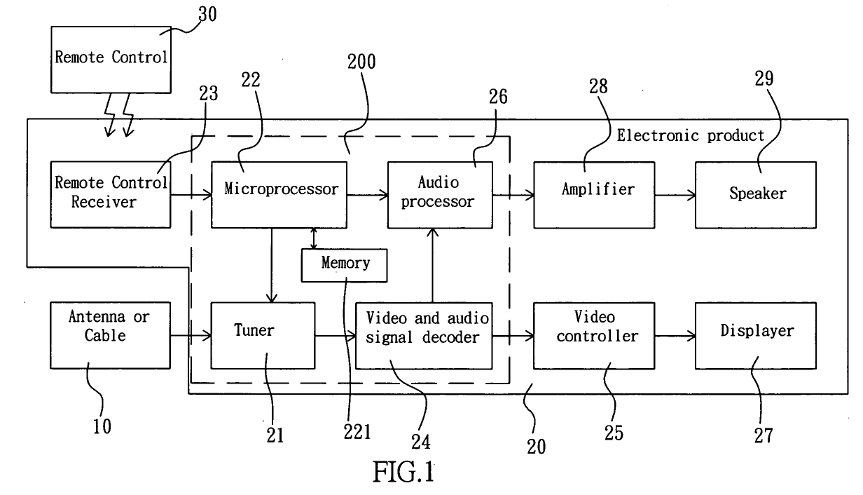

Referring to FIG. 1, which is an apparatus 200 for controlling audio volume when switching electronic product channels. The apparatus 200 is displaced in an electronic product 20 therein. The electronic product 20 comprises a tuner 21, a microprocessor 22, a memory 221, a remote control 23, a video and audio signal decoder 24, a video controller 25, an audio processor 26, a displayer 27, an amplifier 28 and a speaker 29. The apparatus 200 comprises the tuner 21, the microprocessor 22, the memory 221, the video and audio signal decoder 24 and the audio processor 26. The tuner 21 is capable of receiving a video and audio signal transmitted from an antenna or a cable 10. The remote control receiver 23 is capable of receiving a channel signal value or an audio signal value transmitted from a remote control 30. The microprocessor 22 is capable of detecting the channel signal received by a remote control receiver 23, and sequentially controlling the tuner 21 to output a video and audio signal, which is responsive to the channel, to a video and audio signal decoder 24. The video and audio signal decoder is capable of respectively transmitting a video signal to a video controller 25 and transmitting an audio signal to an audio processor 26 after decoding. The video controller 25 is capable of transmitting the video signal to a displayer 27 which results in broadcasting a video image of the channel by the displayer 27. The audio processor 26 is capable of decoding an audio signal, and sequentially transmitting the decoded audio signal to an amplifier 28, and finally broadcasting the audio volume via the speaker 29. When the microprocessor 22 of the apparatus 200 detects the channel signal value, the audio processor 26 outputs the audio volume value in response to the channel signal value which result in broadcasting the responsive audio volume via the speaker 29. When the microprocessor 22 of the apparatus 200 detects a newly-adjusted audio signal value, the new audio signal value and the responsive channel signal value are saved in the memory 221, and then the microprocessor controls the audio processor 26 to output the new audio volume value via a speaker 29. If the electronic product 20 in accordance with the present invention is irrelative to the output of video image, the video and audio signal decoder 24 can be replaced by the audio signal decoder, and then makes the video controller 25 to directly connect with the microprocessor 26.

Traditionally, electronic product is capable of providing user by pressing the key on remote control or the electronic product to adjust display settings via the function menu of a displayer, or to adjust volume settings broadcasted from a speaker, such as the setting of stereo, surrounding stereo and so on, and then to save those of settings in a memory. Under this circumstance, the volume settings are responsive to each one of the broadcasted channels which results in the same volume setting applying to all the channels.

The present invention relating to the microprocessor 22 of the apparatus 200 can save the newly-adjusted audio signal value and the channel signal value thereof in the memory 221 and sequentially control the audio processor 26 by the microprocessor to output the audio volume value responsive to the broadcasting channel, and finally, broadcast the audio volume in response to each different channel via a speaker 29.

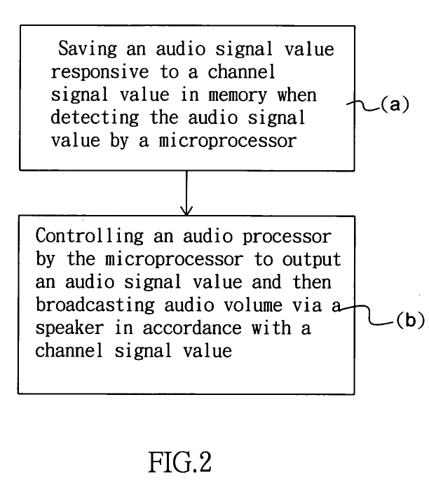

Referring to FIGS. 1 and 2, which relate to the method of the 1^{st} embodiment of an electronic product for controlling audio volume in accordance with the present invention comprises the following steps:

Step (a): When the microprocessor 22 detects an audio signal value, the audio signal value in response to the broadcasted channel is saved in a memory 221, wherein the audio signal value is transmitted from a remote control 30 and received by a remote control receiver 23.

Step (b): When the microprocessor 22 detects a channel signal value, the audio processor 26 outputs an audio signal value in response to the channel signal value, further broadcast the responsive audio volume via a speaker 29, wherein the channel signal value is transmitted from a remote control 30 and received by a remote control receiver 23.

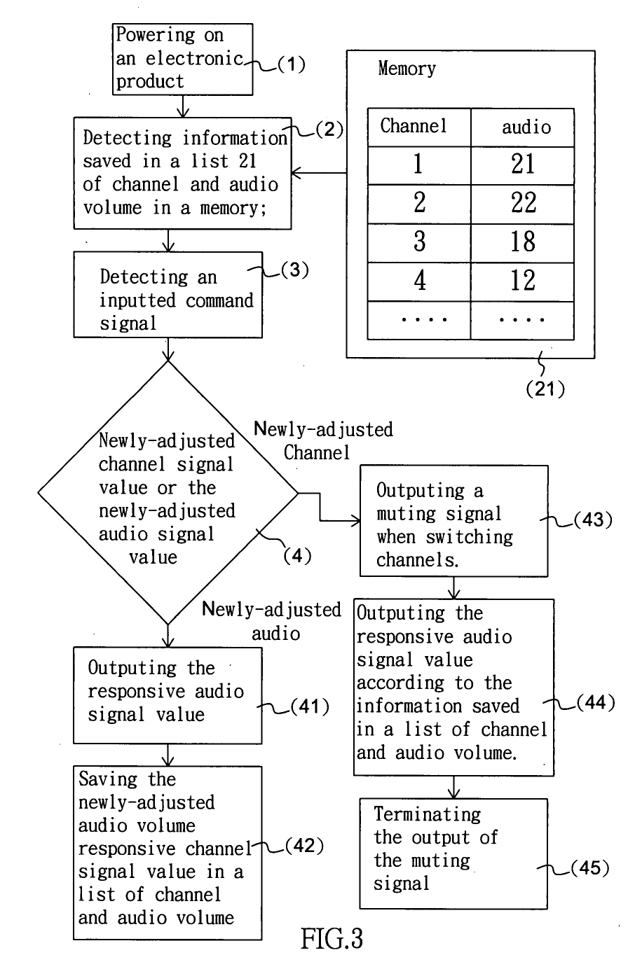

Referring to FIGS. 1 and 3, which relate to the method of the 2^{nd} embodiment of an electronic product for controlling audio volume in accordance with the present invention comprises the following steps:

Step (1):Powering on an electronic product 20;

Step (2):A microprocessor 22 detects values (2) saved in a list 21 of channel and audio volume in a memory 221 therein;

Step (3):A microprocessor 22 detects a command signal transmitted from an input device, e.g. the command signal (3) transmitted from a remote control 30;

Step (4):Confirming the command signal whether is the newly-adjusted channel signal value or the newly-adjusted audio signal value (4). If the command signal is the newly-adjusted audio signal value, the microprocessor 22 controls the audio processor 26 to output the responsive audio signal value (41). Meanwhile, the microprocessor 22 saves the newly-adjusted audio signal value and the responsive channel signal value thereof in a list (21) of channel and audio volume (42) in the memory 221. If the command signal is the newly-adjusted channel signal value, the microprocessor 22 controls the audio processor 26 to output a muting signal (43) when switching channels, and further the microprocessor 22 controls the audio processor 26 to output the audio signal value (44) in response to the newly-adjusted channel value according to the information saved in a list (21) of channel and audio volume, and finally terminating the output of the muting signal (45).

The present invention enables users by pressing the key on remote control 30 or the electronic product 20 to adjust volume settings in response to each channel via the function menu of a displayer 27. For example, when a user set the channel is respectively as channel 31, 32, 33, and 34, the responsive audio volume value is respectively set at the value of 12, 18, 11 and 15 to be broadcasted via speaker 29. Then, each of the audio volume values in response to each channel are predetermined to save in the memory 221. When a user switches channels of an electronic product, the electronic product can output the predetermined audio volume in response to each channel as user's preferable volume in accordance with the present invention.

Therefore, according to the method and the apparatus of the present invention, when the user switches channels of an electronic product, the electronic product can automatically output the predetermined audio volume in response to each channel without re-adjusting the audio volume of the electronic product.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for controlling an audio volume when switching electronic product channels, comprising:
detecting a channel signal value by a microprocessor;
controlling an audio processor by the microprocessor to output an audio signal value in response to the channel signal value; and
outputting an audio volume responsive to the audio signal value via a speaker.

2. The method of claim 1, wherein the channel signal value and the audio signal value thereof are saved in a list of channel and audio volume in a memory.

3. The method of claim 2, wherein further controlling the audio processor by the microprocessor to output a muting signal when switching channels.

4. The method of the claim 2, further comprising:
detecting a newly-adjusted audio signal value by the microprocessor;
saving the newly-adjusted audio signal value and the responsive channel signal value thereof in a list of channel and audio volume in the memory.

5. The method of claim 4, wherein further controlling the audio processor by the microprocessor to output the responsive audio signal value.

6. The method of claim 3, further comprising:
detecting a newly-adjusted audio signal value by the microprocessor;
saving the newly-adjusted audio signal value and the responsive channel signal value thereof in a list of channel and audio volume in the memory.

7. The method of claim 6, wherein further controlling the audio processor by the microprocessor to output the responsive audio signal value.

8. The method of claim 4, wherein the newly-adjusted audio signal value is transmitted by a remote control and received by a remote control receiver.

9. The method of claim 1, wherein the channel signal value is transmitted by a remote control and received by a remote control receiver.

10. An apparatus for controlling an audio volume when switching electronic product channels, comprising: a tuner, a microprocessor, a memory, a signal decoder and an audio processor; the tuner is capable of receiving a signal transmitted from an electronic product; the microprocessor is capable of detecting a channel signal value and an audio signal value, and further controlling the tuner to output an audio signal to the signal decoder according to the channel signal value; the signal decoder is capable of transmitting a decoded signal to the audio processor after the audio signal is decoded; wherein the microprocessor controls the audio processor to output the audio signal value in response to the channel signal value, and sequentially broadcast the responsive audio volume via a speaker.

11. The apparatus of claim 10, wherein the channel signal value and the responsive audio signal value are saved in a list of channel and volume in the memory.

12. The apparatus of claim 11, wherein the microprocessor further controls the audio processor to output a muting signal when switching channels.

13. The apparatus of claim 11, wherein the microprocessor saves the newly-adjusted audio signal value and the responsive channel signal value thereof in a list of channel and volume in the memory when the microprocessor detects a newly-adjusted audio signal value.

14. The apparatus of claim 13, wherein the microprocessor further controls the audio processor to output the responsive audio signal value.

15. The apparatus of claim 12, wherein the microprocessor saves the newly-adjusted audio signal value and the responsive channel signal value thereof in a list of channel and volume in the memory when the microprocessor detects the newly-adjusted audio signal value.

16. The apparatus of claim 15, wherein the microprocessor further controls the audio processor to output the responsive audio signal value.

17. The apparatus of claim 10, wherein the microprocessor further electrically connects to a remote control receiver which is for receiving the channel signal value and the audio signal value transmitted from a remote control.
